(19) United States
(12) Patent Application Publication
(10) Pub. No.: US 2026/0150369 A1
(43) Pub. Date: May 28, 2026

(54) DIRECT BACKSIDE CONTACT

(71) Applicant: International Business Machines Corporation, Armonk, NY (US)

(72) Inventors: Kishore Natarajan, Albany, NY (US); Ruilong Xie, Niskayuna, NY (US); Shay Reboh, GUILDERLAND, NY (US); Tenko Yamashita, Schenectady, NY (US); Kisik Choi, Watervliet, NY (US); HUIMEI ZHOU, Albany, NY (US); Nicolas Jean Loubet, GUILDERLAND, NY (US)

(21) Appl. No.: 18/958,212

(22) Filed: Nov. 25, 2024

(51) Int. Cl. H01L 29/417; H01L 21/283; H01L 29/06; H01L 29/423; H01L 29/66; H01L 29/775; H01L 29/786

(52) U.S. Cl. CPC H10D 64/254; H10D 30/014; H10D 30/43; H10D 62/116; H10D 64/258; H10P 14/40; H10D 30/6735; H10D 30/6757; H10D 62/121

(57) ABSTRACT

A semiconductor structure including a source drain region adjacent to a nanosheet stack, and a source drain contact extending through the source drain region from a frontside of the semiconductor structure to a backside of the semiconductor structure.

### BACKGROUND

The present invention generally relates to semiconductor structures, and more particularly to nanosheet transistor structures having a deep frontside contact enabling formation of direct backside contacts without require a placeholder fabrication scheme.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a source drain region adjacent to a nanosheet stack, and a source drain contact extending through the source drain region from a frontside of the semiconductor structure to a backside of the semiconductor structure.

According to another embodiment of the present invention, a semiconductor structure is provided. The semiconductor structure may include a nanosheet stack comprising nanosheet channels, a source drain region adjacent to the nanosheet stack, where the source drain region directly contacts sidewalls of each of the nanosheet channels, and a source drain contact extending through the source drain region from a frontside of the semiconductor structure to a backside of the semiconductor structure, where a topmost surface of the source drain contact is above a topmost channel of the nanosheet channels, and where a bottommost surface of the source drain contact is below a bottommost channel of the nanosheet channels.

According to another embodiment of the present invention, a semiconductor structure is provided. The semiconductor structure may include a first source drain region adjacent to a nanosheet stack, a first source drain contact extending through the first source drain region from a frontside of the semiconductor structure to a backside of the semiconductor structure, a second source drain region adjacent to the nanosheet stack, and a second source drain contact extending through the second source drain region from a frontside of the semiconductor structure to a backside of the semiconductor structure.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2, 3, and 4 are cross-sectional views of the semiconductor structure during an intermediate step of a method of fabricating nanosheet transistor structures according to an exemplary embodiment;

FIGS. 5, 6, and 7 are cross-sectional views of the semiconductor structure after forming and patterning sacrificial gates according to an exemplary embodiment;

FIGS. 8, 9, and 10 are cross-sectional views of the semiconductor structure after selectively removing the second sacrificial nanosheets according to an exemplary embodiment;

FIGS. 11, 12, and 13 are cross-sectional views of the semiconductor structure after forming a spacer material according to an exemplary embodiment;

FIGS. 14, 15, and 16 are cross-sectional views of the semiconductor structure after removing portions of the nanosheet stacks, forming inner spacers, and forming source drain regions according to an exemplary embodiment;

FIGS. 17, 18, and 19 are cross-sectional views of the semiconductor structure after forming a dielectric layer and removing the gate hard masks according to an exemplary embodiment;

FIGS. 20, 21, and 22 are cross-sectional views of the semiconductor structure after selectively removing the sacrificial gates and the first sacrificial nanosheets, and forming gate structures according to an exemplary embodiment;

FIGS. 23, 24, and 25 are cross-sectional views of the semiconductor structure after forming gate structures and self-aligned gate caps according to an exemplary embodiment;

FIGS. 26, 27, and 28 are cross-sectional views of the semiconductor structure after forming an additional dielectric layer and forming frontside contact trenches according to an exemplary embodiment;

FIGS. 29, 30, and 31 are cross-sectional views of the semiconductor structure after forming sacrificial sidewall spacers according to an exemplary embodiment;

FIGS. 32, 33, and 34 are cross-sectional views of the semiconductor structure after extending the frontside contact trenches through the source drain regions and the spacer material, and into the substrate forming a second sacrificial liner according to an exemplary embodiment;

FIGS. 35, 36, and 37 are cross-sectional views of the semiconductor structure after removing the sacrificial sidewall spacers and forming source drain contacts, middle-of-line, back-end-of-line, and attaching a carrier wafer according to an exemplary embodiment;

FIGS. 38, 39, and 40 are cross-sectional views of the semiconductor structure after flipping the assembly and removing the substrate according to an exemplary embodiment;

FIGS. 41, 42, and 43 are cross-sectional views of the semiconductor structure after forming a backside dielectric layer according to an exemplary embodiment; and

FIGS. 44, 45, and 46 are cross-sectional views of the semiconductor structure after shown after forming backside vias and backside wiring layers according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, including gate-all-around transistor devices and nanosheet transistor devices, have known advantages over conventional transistor structures in terms of density, performance, power consumption, and integration. However, fabricating device contacts on a backside of the wafer presents unique challenges. More specifically, for example, conventional placeholder fabrication techniques run the risk of causing damage to the gate hard mask, resulting spacer loss and epi nodules. The placeholder-based backside contact also involves high aspect ratio patterning, which increases risk of gate bending or collapse. Therefore, it is desired to form backside contacts without need of creating deep placeholders under source drain regions.

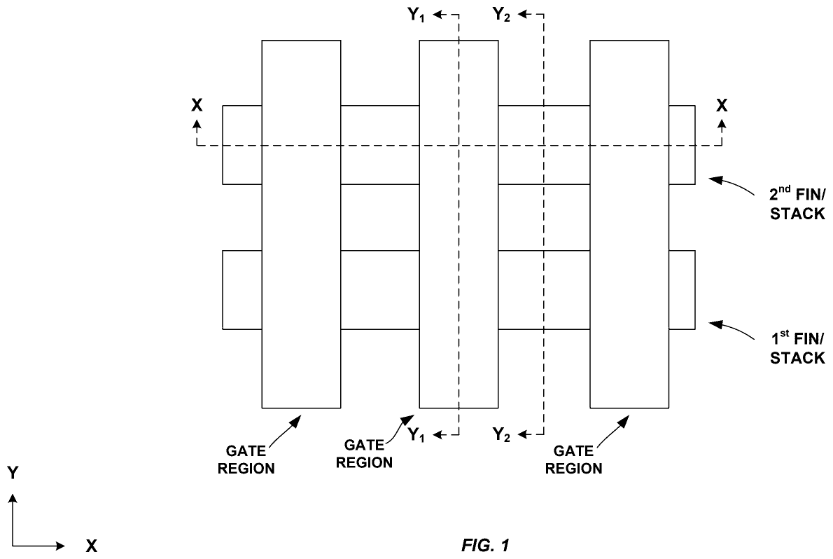

The present invention generally relates to semiconductor structures, and more particularly to nanosheet transistor structures having a deep frontside contact enabling formation of direct backside contacts without require a placeholder fabrication scheme. More specifically, the nanosheet transistor structures and associated method disclosed herein enable a novel solution for providing direct backside source drain contacts without the need of forming any placeholders. Exemplary embodiments of nanosheet transistor structures having a deep frontside contact are described in detail below by referring to the accompanying drawings in FIGS. 1 to 46. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows a first fin/stack, a second fin/stack, and gate regions situated perpendicular to the fins/stacks. FIGS. 1-46 represent cross section views oriented as indicated in FIG. 1

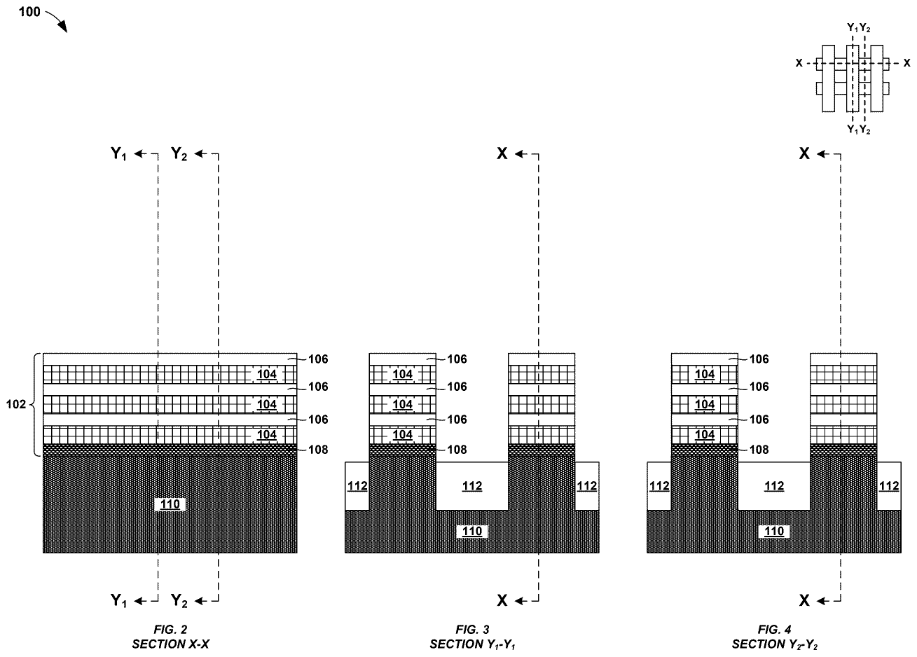

Referring now to FIGS. 2, 3, and 4, a structure 100 is shown during an intermediate step of a method of fabricating stacked transistor structures according to an embodiment of the invention. FIG. 2 depicts a cross-sectional view of the structure 100 taken along line X-X, FIG. 3 depicts a cross-sectional view of the structure 100 taken along line Y₁-Y₁, and FIG. 4 depicts a cross-sectional view of the structure 100 taken along line Y₂-Y₂.

The structure 100 illustrated in FIGS. 2-4 includes nanosheet stacks 102, or fins, formed from an alternating series of first silicon germanium (SiGe) sacrificial nanosheets 104 (hereinafter “first sacrificial nanosheets 104”), silicon (Si) nanosheet channels 106 (hereinafter “nanosheet channels 106”), and second silicon germanium (SiGe) sacrificial nanosheets 108 (hereinafter “second sacrificial nanosheets 108”), as illustrated. The nanosheet stacks 102 are formed on a silicon substrate 110 (hereinafter “substrate 110”). Although only a limited number of nanosheet stacks 102 and nanosheet layers are shown, one or more additional nanosheet stacks and/or nanosheets can optionally be epitaxially grown in an alternating fashion, and the properties of any additional nanosheets are the same as the corresponding nanosheets described herein.

According to embodiments of the present disclosure, the first sacrificial nanosheets 104 have a different germanium concentration than the second sacrificial nanosheets 108. In at least one embodiment, the second sacrificial nanosheets 108 have a higher germanium concentration than the first sacrificial nanosheets 104. More specifically, for example, the second sacrificial nanosheets 108 may have a germanium concentration ranging from about 45 to about 70 percent, while the first sacrificial nanosheets 104 may have a germanium concentration ranging from about 15 to about 40 percent. In all cases, the different germanium concentrations are designed to allow for each of the first sacrificial nanosheets 104 and the second sacrificial nanosheets 108 to be etched selective to one another. As such, other germanium concentrations are explicitly contemplated.

In one or more embodiments, the nanosheet stacks 102 are formed by epitaxially growing one layer and then the next until a desired number and a desired thickness of each layer is achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be undoped or can be doped during deposition (in-situ doped) by adding dopants, n-type dopants (e.g., phosphorus or arsenic) or p-type dopants (e.g., boron or gallium), depending on the type of transistor. For example, in at least one embodiment, the nanosheet channels 106 are doped, undoped or some combination thereof.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments, epitaxial growth and/or deposition processes are selective to forming on semiconductor surfaces, and generally do not deposit material on exposed surfaces, such as silicon dioxide or silicon nitride surfaces.

In some embodiments, the gas source for the deposition of epitaxial semiconductor material includes a silicon containing gas source, a germanium containing gas source, or a combination thereof. For example, an epitaxial silicon layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

The substrate 110 may include a bulk semiconductor or a layered semiconductor such as Si/SiGe, a silicon-on-insulator (SOI), or a SiGe-on-insulator (SGOI). Bulk substrate materials may include undoped Si, n-doped Si, p-doped Si, single crystal Si, polycrystalline Si, amorphous Si, Ge, SiGe, SiC, SiGeC, Ga, GaAs, InAs, InP and all other III/V or II/VI compound semiconductors. In at least one embodiment, the substrate 110 may be made from undoped silicon.

Known processing techniques have been applied to the alternating layers to form the nanosheet stacks 102 shown. For example, the known processing techniques can include the formation of hard masks (not shown) over the topmost layer of the nanosheet stacks 102. The hard masks can be formed by first depositing the hard mask material (for example silicon nitride) onto the topmost layer of the nanosheet stacks 102 using, for example, chemical vapor deposition (CVD), plasma enhanced CVD (PECVD) or any suitable technique for dielectric deposition that does not induce a physical or chemical change to the topmost layer of the nanosheet stacks 102. According to an exemplary embodiment, the hard mask material is deposited onto the topmost nanosheet channels 106 at the top of the nanosheet stacks 102 and then patterned into a plurality of the individual hard masks. Patterning the hard mask is commensurate with a desired footprint and location of the nanosheet stacks 102 shown in FIGS. 2-4, which will subsequently be used to form the channel regions of semiconductor devices disclosed herein. According to an exemplary embodiment, RIE is used to transfer the hard mask pattern into the alternating layers to form the nanosheet stacks 102, and into the substrate 110, as shown.

Next, shallow trench isolation regions 112 (hereinafter “STI regions 112”) are formed according to known techniques. The STI regions 112 are formed at the bottom of trenches in the substrate 110 formed during patterning of the nanosheet stacks 102. Specifically, a dielectric material is deposited at the bottom of trenches in the substrate 110 to isolate adjacent devices from one another according to known techniques. The STI regions 112 may be formed from any appropriate dielectric material including, for example, silicon oxide (SiOₓ) or silicon nitride (SiₓN_{y}).

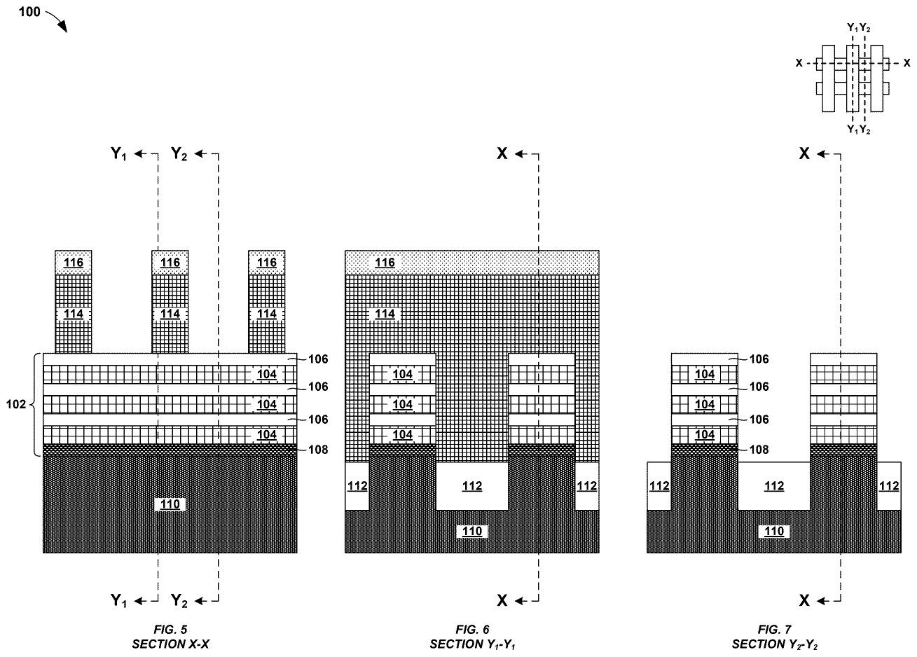

Referring now to FIGS. 5, 6, and 7, the structure 100 is shown after forming and patterning sacrificial gates 114 according to an embodiment of the invention. FIG. 5 depicts a cross-sectional view of the structure 100 taken along line X-X, FIG. 6 depicts a cross-sectional view of the structure 100 taken along line Y₁-Y₁, and FIG. 7 depicts a cross-sectional view of the structure 100 taken along line Y₂-Y₂.

First, sacrificial gate material is blanket deposited over and around the nanosheet stacks 102 according to known techniques. Specifically, for example, a relatively thick layer of amorphous silicon is blanket deposited directly on the nanosheet stacks 102. In this manner, the sacrificial gates 114 completely cover the nanosheet stacks 102.

Next, a gate hard mask material is formed over the structure 100. According to an exemplary embodiment, the gate hard mask material is deposited onto the sacrificial gate material and then patterned into a plurality of gate hard masks 116. The gate hard masks 116 define gate regions of individual devices in the structure 100.

Next, the pattern created by the gate hard masks 116 is transferred into the sacrificial gate material to form the sacrificial gates 114. Specifically, portions of the sacrificial gate material are etched or removed selective to the gate hard masks 116, as illustrated. The portions of the sacrificial gate material can be removed using a silicon RIE process.

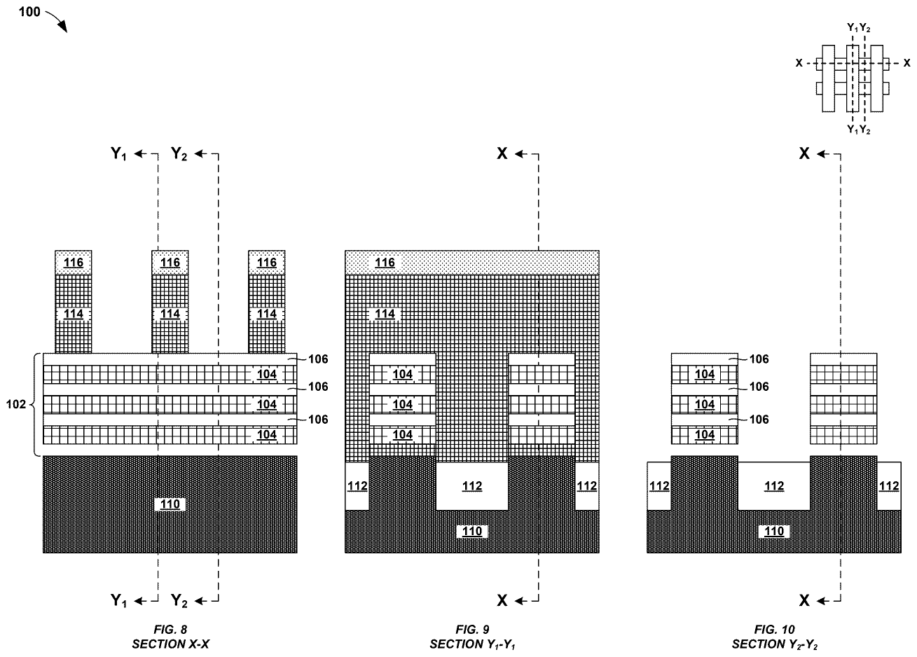

Referring now to FIGS. 8, 9, and 10, the structure 100 is shown after selectively removing the second sacrificial nanosheets 108 according to an embodiment of the invention. FIG. 8 depicts a cross-sectional view of the structure 100 taken along line X-X, FIG. 9 depicts a cross-sectional view of the structure 100 taken along line Y₁-Y₁, and FIG. 10 depicts a cross-sectional view of the structure 100 taken along line Y₂-Y₂.

More specifically, the second sacrificial nanosheets 108 are etched and removed selective to the first sacrificial nanosheets 104 and/or the nanosheet channels 106 according to known techniques. Doing so is made possible by the different concentrations of germanium. In this case, the layers with the relatively higher germanium concentration are removed selective to layers with the relatively lower germanium concentrations.

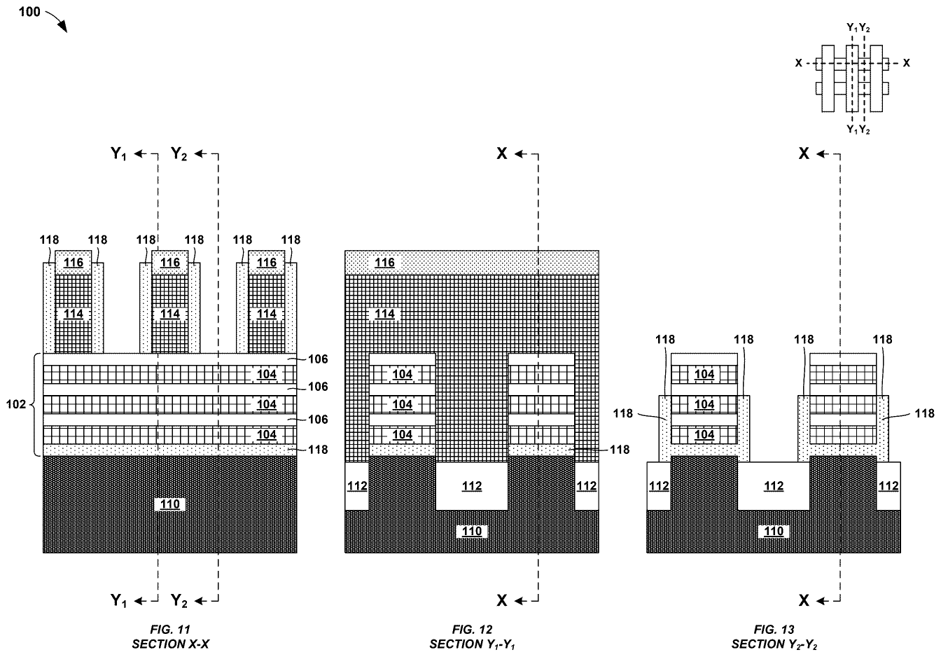

Referring now to FIGS. 11, 12, and 13, the structure 100 is shown after forming a spacer material 118 according to an embodiment of the invention. FIG. 11 depicts a cross-sectional view of the structure 100 taken along line X-X, FIG. 12 depicts a cross-sectional view of the structure 100 taken along line Y₁-Y₁, and FIG. 13 depicts a cross-sectional view of the structure 100 taken along line Y₂-Y₂.

The spacer material 118 is deposited directly on exposed surfaces of the structure 100 according to known techniques. Specifically, for example, a relatively thin layer of silicon nitride is conformally deposited as illustrated. In some embodiments, for example, the spacer material 118 may be composed of SiN, SiBCN, SiOCN, SiOC, or any other combination of low-k materials. The term “low-k” as used throughout the present application denotes a dielectric material that has a dielectric constant of less than 4.0. According to embodiments of the present disclosure, the spacer material 118 substantially fills the space created by removing the second sacrificial nanosheets 108, and functions to isolate the nanosheet stacks 102 from the substrate 110. Further, according to embodiments of the present disclosure, the spacer material 118 substantially covers exposed vertical sidewalls of the nanosheet stacks 102 and exposed vertical sidewalls of the sacrificial gates 114, as illustrated in FIG. 13.

After deposition, in at least an embodiment, portions of the spacer material 118 are selectively removed or etched from horizontal surfaces according to known techniques. Doing so will generally expose top surfaces of the nanosheet stacks 102, the gate hard masks 116, and the STI regions 112, as illustrated. Further, etching may continue until the spacer material 118 is recessed below top surfaces of the nanosheet stacks 102 and the gate hard masks 116.

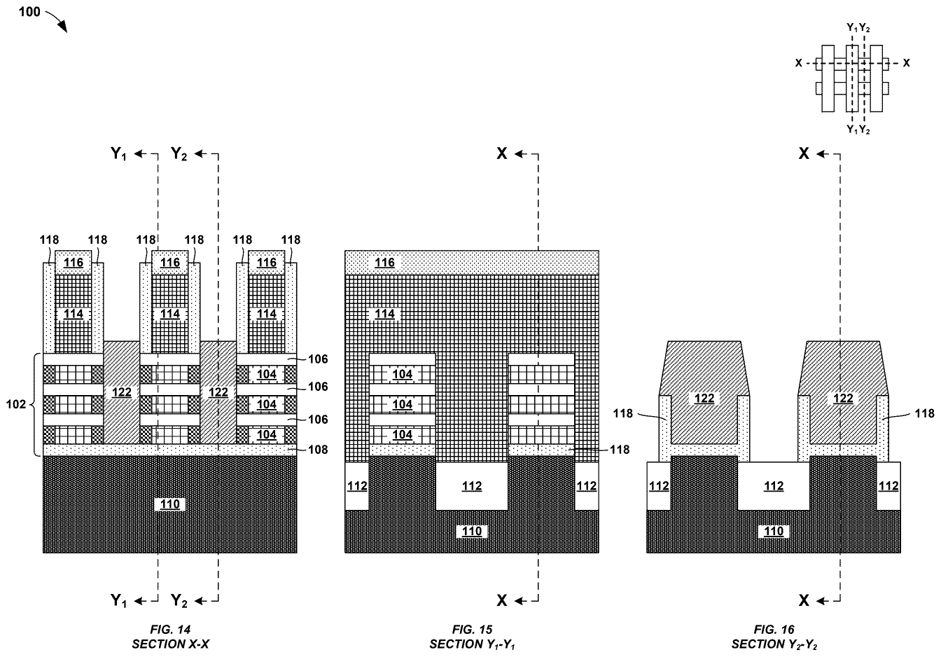

Referring now to FIGS. 14, 15, and 16, the structure 100 is shown after removing portions of the nanosheet stacks 102, forming inner spacers 120, and forming source drain regions 122 according to an embodiment of the invention. FIG. 14 depicts a cross-sectional view of the structure 100 taken along line X-X, FIG. 15 depicts a cross-sectional view of the structure 100 taken along line Y₁-Y₁, and FIG. 16 depicts a cross-sectional view of the structure 100 taken along line Y₂-Y₂.

Portions of the nanosheet stacks 102 are etched and removed from between the sacrificial gates 114 according to known techniques. Specifically, the pattern created by the gate hard masks 116 and the spacer material 118 is transferred into the nanosheet stacks 102. In doing so, portions of the first sacrificial nanosheets 104 and the nanosheet channels 106, are removed selective to the gate hard masks 116 and the spacer material 118, as illustrated.

In an embodiment, portions of the nanosheet stacks 102 are removed using an anisotropic etch such as, for example, reactive ion etching. Doing so may require a series of multiple etching steps using different etch chemistries as is well known in the art. Etching is designed to define source drain regions and expose ends of individual nanosheet layers. In all cases, etching continues until the spacer material 118 is exposed and without exposing the substrate 110, as illustrated.

Next, the first sacrificial nanosheets 104 are laterally recessed to make room for the inner spacers 120. In one or more embodiments, the first sacrificial nanosheets 104 are laterally recessed using a hydrogen chloride (HCl) gas isotropic etch process, which etches silicon germanium without attacking silicon. In other embodiments, the first sacrificial nanosheets 104 are laterally recessed using a ClF3 etch process. Cavities (not shown) are formed by spaces that were occupied by the removed portions of the first sacrificial nanosheets 104.

The inner spacers 120 are formed by first conformally depositing a spacer material over the structure 100 to fill the cavities created by laterally recessing the first sacrificial nanosheets 104. The conformal spacer material is then isotropically etched to remove all portions except those remaining in the cavities and forming the inner spacers 120. In one or more embodiments, the inner spacers 120 are made from a nitride containing material, for example silicon nitride (SiN). Although the inner spacers 120 shown in FIG. 14 are formed from a nitride containing material, they can be formed from any material for which subsequent device fabrication operations are not very selective. Selectivity, as used in the present description, refers to the tendency of a process operation to impact a particular material. One example of low selectivity is a relatively slow etch rate. One example of a higher or greater selectivity is a relatively faster etch rate. For the described embodiments, a material for the inner spacers 120 can be selected based on a selectivity of subsequent device fabrication operations for the selected material being below a predetermined threshold.

The inner spacers 120 are positioned such that subsequent etching processes used to remove the first sacrificial nanosheets 104 during device fabrication do not also attack subsequently formed source drain regions.

Next, the source drain regions 122 are formed using an epitaxial layer growth process on the exposed ends of the nanosheet channels 106 according to known techniques. Typically, in-situ doping is used to dope the source drain regions 122, thereby creating the necessary junctions of the semiconductor device. Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a P-type piece of silicon, rich in holes, and an N-type piece of silicon, rich in electrons. N-type and P-type devices are formed by using different types of dopants to select regions of the device to form the necessary junction(s). For example, N-type devices can be formed by doping with arsenic (As) or phosphorous (P), and p-type devices can be formed by doping with implanting boron (B).

According to embodiments of the present invention, at least some of the source drain regions 122 are of a first-type, for example, P-type, and at least some of the source drain regions 122 are of a second-type, for example, N-type.

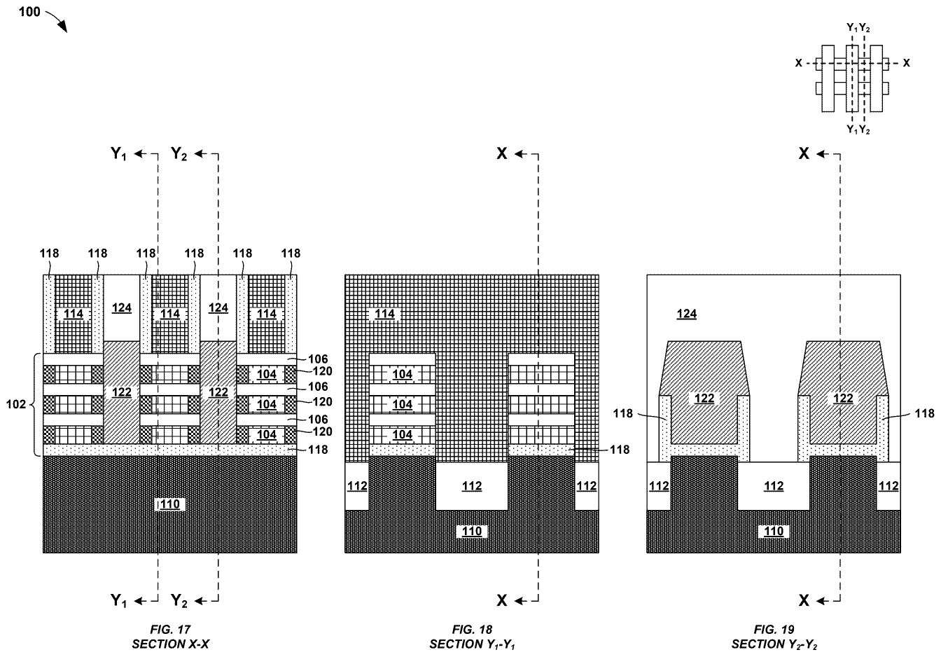

Referring now to FIGS. 17, 18, and 19, the structure 100 is shown after forming a dielectric layer 124 and removing the gate hard masks 116 according to an embodiment of the invention. FIG. 17 depicts a cross-sectional view of the structure 100 taken along line X-X, FIG. 18 depicts a cross-sectional view of the structure 100 taken along line Y₁-Y₁, and FIG. 19 depicts a cross-sectional view of the structure 100 taken along line Y₂-Y₂.

The dielectric layer 124 is blanket deposited an interlayer dielectric material over the structure 100 according to known techniques. Specifically, the dielectric layer 124 is formed on the source drain regions 122, as illustrated in FIG. 19, and substantially fills the remaining space between the spacer material 118, as illustrated in FIG. 17.

The dielectric layer 124 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the dielectric layer 124. Using a self-planarizing dielectric material as the dielectric layer 124 can avoid the need to perform a subsequent planarizing step.

After the dielectric layer 124 is formed, the structure is polished according to known techniques, such as, for example, chemical mechanical polishing techniques. Specifically, the dielectric layer 124, the spacer material 118, and the gate hard masks 116 are polished until the gate hard masks 116 are removed and topmost surfaces of the sacrificial gates 114 are exposed, as illustrated.

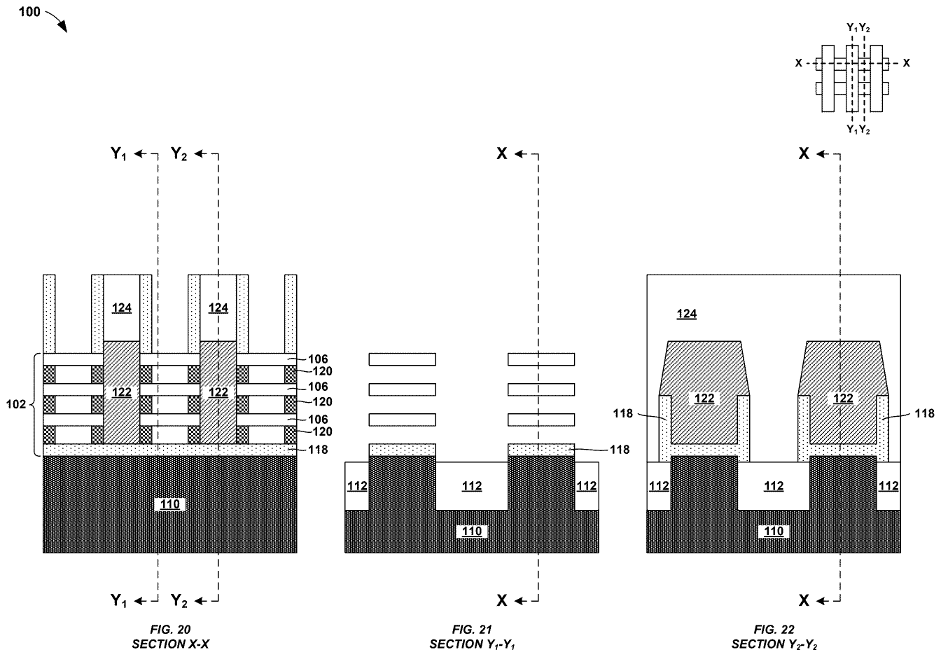

Referring now to FIGS. 20, 21, and 22, the structure 100 is shown after selectively removing the sacrificial gates 114 and the first sacrificial nanosheets 104, and forming gate structures 126 according to an embodiment of the invention. FIG. 20 depicts a cross-sectional view of the structure 100 taken along line X-X, FIG. 21 depicts a cross-sectional view of the structure 100 taken along line Y₁-Y₁, and FIG. 22 depicts a cross-sectional view of the structure 100 taken along line Y₂-Y₂.

First, the sacrificial gates 114 and the first sacrificial nanosheets 104 are selectively removed according to known techniques. Specifically, the sacrificial gates 114 are etched and removed selective to the spacer material 118 and the nanosheet stacks 102 according to known techniques. Next, the first sacrificial nanosheets 104 are etched and removed selective to the nanosheet channels 106 and the inner spacers 120 according to known techniques. Doing so is made possible by the different concentrations of germanium. In this case, the layers with germanium are removed selective to layers without germanium.

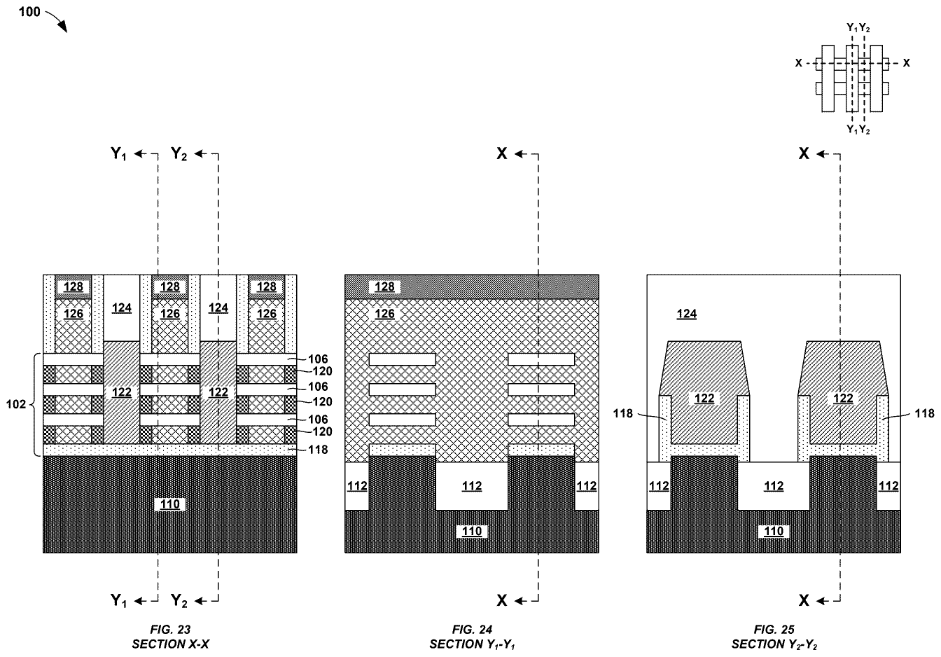

Referring now to FIGS. 23, 24, and 25, the structure 100 is shown after forming gate structures 126 and self-aligned gate caps 128 according to an embodiment of the invention. FIG. 23 depicts a cross-sectional view of the structure 100 taken along line X-X, FIG. 24 depicts a cross-sectional view of the structure 100 taken along line Y₁-Y₁, and FIG. 25 depicts a cross-sectional view of the structure 100 taken along line Y₂-Y₂.

The gate structures 126, include a gate dielectric and a work function metal, are formed according to known techniques. First, the gate dielectric (not shown) is conformally deposited directly on exposed surfaces of the structure 100 within the gate cavities or openings and spaces left by removing the sacrificial gates 114 and the first sacrificial nanosheets 104 according to known techniques. For example, the gate dielectric is conformally deposited on exposed surfaces of the nanosheet channels 106 and the inner spacers 120.

The gate dielectric is composed of any known gate dielectric materials, for example, oxide, nitride, and/or oxynitride. In an example, the gate dielectric can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure including different gate dielectric materials. For example, a silicon dioxide layer and a high-k gate dielectric layer can be formed and used together as the gate dielectric. In at least one embodiment, the gate dielectric is composed of hafnium oxide.

Next, the work function metal (not shown) is conformally deposited on the gate dielectric formed within the gate cavities according to known techniques. In at least one embodiment, the work function metal is made of the same conductive material across the entire structure. In at least another embodiment, the work function metal is made from different conductive materials in each of the devices illustrated the figures. In doing so, the different conductive materials would be deposited successively according to the design parameters and desired operation characteristics.

The work function metal can include any known conductive gate material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or titanium cabon (TiC), titanium alumunm (TiAl), titanium aluminum cabron (TiAlC), or multilayered combinations thereof. In some embodiments, the work function metal can include an nFET gate metal. In other embodiments, the work function metal can include a pFET gate metal. When multiple gate cavities are formed, as illustrated herein, embodiments of the present invention explicitly contemplate forming an nFET in at least one of the gate cavities and a pFET in at least another one of the gate cavities.

In some embodiments, a gate metal or a contact metal, is deposited directly on the work function metal, and fills the gate cavities. The gate metal may include any suitable conductive material, such as, for example, copper, ruthenium, aluminum, tungsten, cobalt, or alloys thereof. After deposition, excess gate metal can be polished using known techniques.

Next, the self-aligned gate caps 128 (hereinafter gate caps 128) are formed according to known techniques. First, the gate structures 126 are recessed according to known techniques. Specifically, for example, one or more suitable etching techniques such as dry etch, wet etch, or combination of both may be used to recess the gate structures 126. In all cases, the chosen etching technique shall be selective to underlying structures, such as for example, the spacer material 118 and the dielectric layer 124, as illustrated.

Next, the gate caps 128 of the present embodiment are formed directly on the recessed gate structures 126, and more specifically fill the voids created by recessing the gate structures 126 as illustrated and according to known techniques. Specifically, a blanket dielectric layer is deposited across the structure 100 followed by a chemical mechanical polishing technique to remove excess unwanted dielectric material from upper surfaces of the structure 100. As a result, topmost surfaces of the gate caps 128 will be flush, or substantially flush, with topmost surfaces of the spacer material 118 and the dielectric layer 124.

The spacer material 118 and the gate caps 128 are provided to separate and electrically insulate the gate structures 126 from subsequently formed structures, such as, for example, contact structures. The spacer material 118 are critical for electrically insulating the gate structures 126 from adjacent source drain regions 122 or subsequently formed contact structures, as described below. The gate caps 128 may further protect the gate structures 126 during subsequent processing. In at least one embodiment, the spacer material 118 and the gate structures 126 are both composed of SiN, SiBCN, SiOCN, SiOC, or other known equivalents.

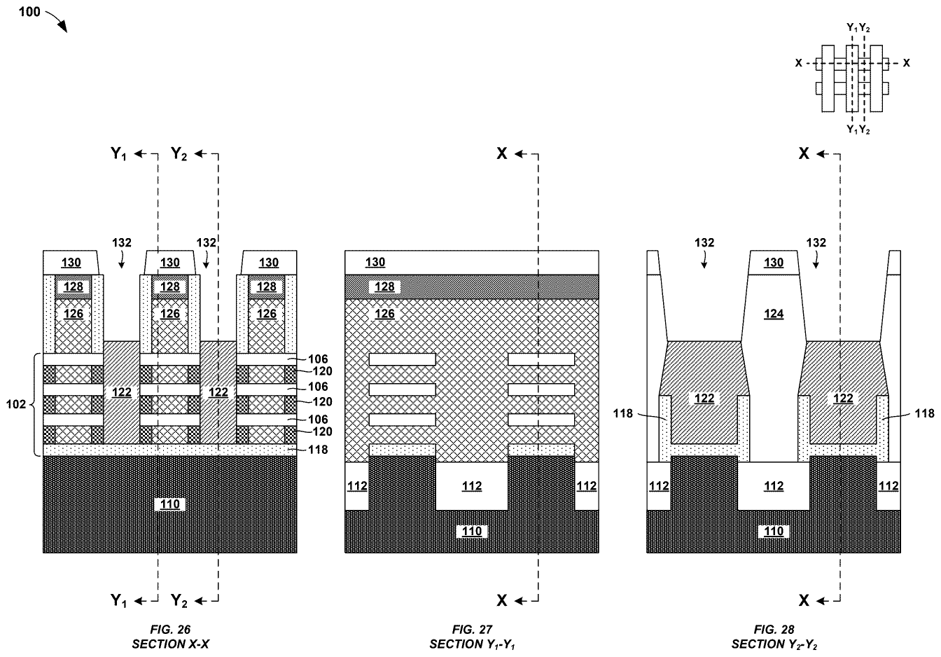

Referring now to FIGS. 26, 27, and 28, the structure 100 is shown after forming an additional dielectric layer 130 and forming frontside contact trenches 132 according to an embodiment of the invention. FIG. 26 depicts a cross-sectional view of the structure 100 taken along line X-X, FIG. 27 depicts a cross-sectional view of the structure 100 taken along line Y₁-Y₁, and FIG. 28 depicts a cross-sectional view of the structure 100 taken along line Y₂-Y₂.

The additional dielectric layer 130 is deposited and subsequently patterned to expose certain frontside portions of the structure 100 according to known techniques. Specifically, an interlayer dielectric material is blanket deposited over the structure 100. The additional dielectric layer 130 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In an embodiment, the additional dielectric layer 130 is made from the same material as the dielectric layer 124. In another embodiment the additional dielectric layer 130 is made from a different material as the dielectric layer 124. In all cases, both the additional dielectric layer 130 and the dielectric layer 124 should be made from materials which can be etched selective to surrounding structures, for example, the spacer material 118.

Next the frontside contact trenches 132 are formed according to known techniques. For example, known patterning techniques are applied to remove portions of the additional dielectric layer 130 and the dielectric layer 124 to expose topmost surfaces of the source drain regions 122, as illustrated. The frontside contact trenches 132 are self-aligned to the spacer material 118 in the x-direction, as illustrated in FIG. 26, and bounds by an appropriate mask in the y-direction, as illustrated in FIG. 28.

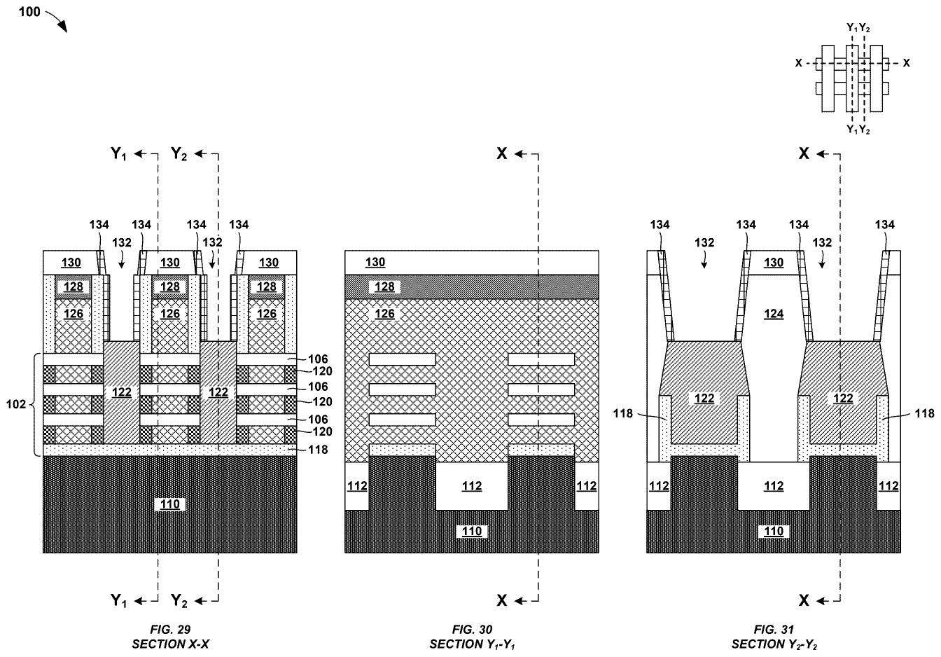

Referring now to FIGS. 29, 30, and 31, the structure 100 is shown after forming sacrificial sidewall spacers 134 according to an embodiment of the invention. FIG. 29 depicts a cross-sectional view of the structure 100 taken along line X-X, FIG. 30 depicts a cross-sectional view of the structure 100 taken along line Y₁-Y₁, and FIG. 31 depicts a cross-sectional view of the structure 100 taken along line Y₂-Y₂.

The sacrificial sidewall spacers 134 are formed by first depositing a conformal layer of dielectric material on top of the structure 100 according to known techniques. Specifically, the layer of dielectric material may be deposited directly on top of the structure and within the frontside contact trenches 132. In an embodiment, the layer of dielectric material can include, for example, silicon nitride or silicon oxide, or SiOCN, SiC, TiOx, AlOx, etc. It may be preferable, in some cases, to fabricate the sacrificial sidewall spacers 134 from a material having a substantially different etch rate than that of the surrounding materials, for example the source drain regions 122. In an embodiment, the layer of dielectric material may preferably include an oxide, for example, titanium oxide.

The layer of dielectric material can be deposited with a conformal deposition technique, using any known atomic layer deposition technique, molecular layer deposition techniques, or other known conformal deposition techniques. In an embodiment, the layer of dielectric material can have a substantially conformal and uniform thickness ranging from about 5 nm to about 20 nm, and ranges there between.

Next, a directional anisotropic etching technique may be used to remove portions of the layer of dielectric material from horizontal surfaces of the structure 100, while leaving it on the sidewalls of the frontside contact trenches 132. For example, a reactive-ion-etching technique may be used to remove portions of the layer of dielectric material from topmost surfaces of the source drain regions 122 and the additional dielectric layer 130, as illustrated. The portions of the layer of dielectric material remaining along opposite sidewalls of the frontside contact trenches 132 form the sacrificial sidewall spacers 134. Furthermore, the sacrificial sidewall spacers 134 should include materials that would allow portions of the source drain regions 122 to be subsequently removed selective to the sacrificial sidewall spacers 134, as described in more detail below. Here, it should also be noted that the sacrificial sidewall spacers 134 depicted in the figures are for illustration purposes and generally can have a slightly different shape from those shown. For example, the sacrificial sidewall spacers 134 can have rounded corners which may naturally form during the directional etching process as is known in the art.

The sacrificial sidewall spacers 134 will have a lateral width substantially equal to the conformal thickness of the layer of dielectric material above. In an embodiment, the lateral width of the sacrificial sidewall spacers 134 may preferably be sublithographic, or smaller than a lithographic minimum dimension. The term “sublithographic” may refer to a dimension or size less than current dimensions achievable by photolithographic processes, and the term “lithographic” or “lithographic minimum dimension” may refer to a dimension or size equal to or greater than current dimensions achievable by photolithographic processes. The sublithographic and lithographic dimensions may be determined by a person of ordinary skill in the art at the time the application is filed. While a “lithographic minimum dimension” and a “sublithographic dimension” are defined only in relation to a lithography tool and normally change from generation to generation of semiconductor technology, it is understood that the lithographic minimum dimension and the sublithographic dimension are to be defined in relation to the best performance of lithography tools available at the time of semiconductor manufacturing. As of 2015, the lithographic minimum dimension is about 20 nm and is expected to shrink in the future. In an embodiment, for example, the sacrificial sidewall spacers 134 may have a lateral width ranging from about 5 nm to about 15 nm, and ranges there between. It is possible to adjust spacer width based on etch bias or loss of material during the anisotropic etching process to meet final technology target dimensions. In all cases, the resulting lateral thickness of the sacrificial sidewall spacers 134 should be large enough to prevent the subsequent removal of all the source drain regions 122, but small enough to enable successful extend the frontside contact trenches 132 into the source drain regions 122, as described in more detail below.

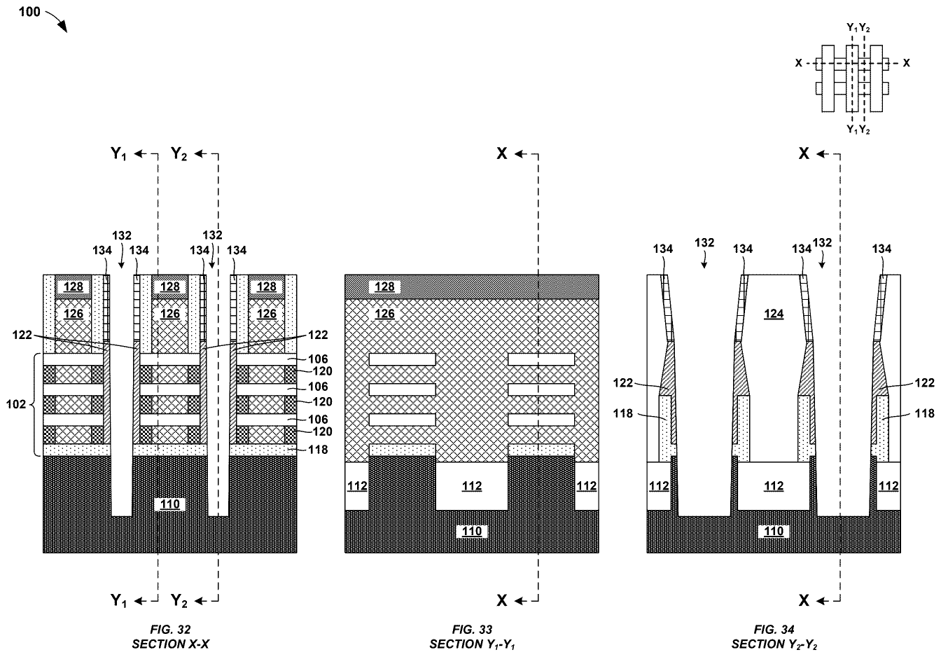

Referring now to FIGS. 32, 33, and 34, the structure 100 is shown after extending the frontside contact trenches 132 through the source drain regions 122 and the spacer material 118, and into the substrate 110 according to an embodiment of the invention. FIG. 32 depicts a cross-sectional view of the structure 100 taken along line X-X, FIG. 33 depicts a cross-sectional view of the structure 100 taken along line Y₁-Y₁, and FIG. 34 depicts a cross-sectional view of the structure 100 taken along line Y₂-Y₂.

The frontside contact trenches 132 are extended according to known techniques. Specifically, known etching techniques are used to remove portions of the source drain regions 122, the spacer material 118, and the substrate 110 thereby extending the frontside contact trenches 132, as illustrated. In doing so, portions of the source drain regions 122, the spacer material 118, and the substrate 110 are etched and removed selective to the sacrificial sidewall spacers 134 according to known techniques.

In an embodiment, portions of the source drain regions 122, the spacer material 118, and the substrate 110 are removed using an anisotropic etch such as, for example, reactive ion etching. Doing so may require a series of multiple etching steps using different etch chemistries as is well known in the art. Etching continues at least until the frontside contact trenches 132 extends into the substrate 110. For example, according to at least one embodiment, the frontside contact trenches 132 extend into the substrate 110 to a level at or below bottommost surfaces of the STI regions 112.

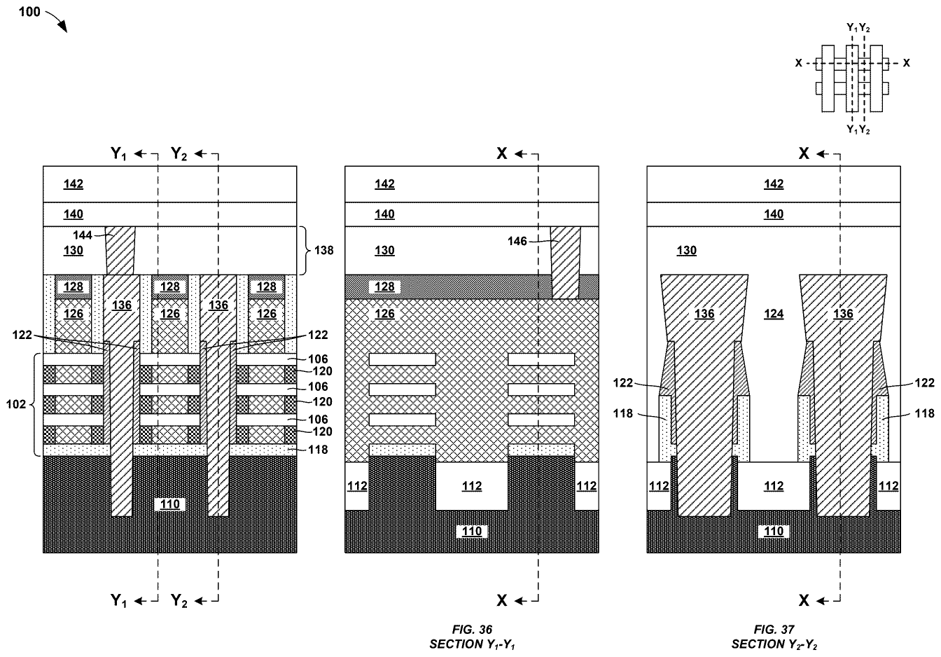

Referring now to FIGS. 35, 36, and 37, the structure 100 is shown after removing the sacrificial sidewall spacers 134 and forming source drain contacts 136, middle-of-line 138, back-end-of-line 140, and attaching a carrier wafer 142 according to an embodiment of the invention. FIG. 35 depicts a cross-sectional view of the structure 100 taken along line X-X, FIG. 36 depicts a cross-sectional view of the structure 100 taken along line Y₁-Y₁, and FIG. 37 depicts a cross-sectional view of the structure 100 taken along line Y₂-Y₂.

First, the portions of the sacrificial sidewall spacers 134 are removed according to known techniques. Specifically, exposed the sacrificial sidewall spacers 134 are selectivly removed using known etching techniques suitable to remove silicon nitride selective to the surrounding materials. In an embodiment, the sacrificial sidewall spacers 134 are removed using an anisotropic etch such as, for example, reactive ion etching. In another embodiment, the sacrificial sidewall spacers 134 are removed using an isotropic etch such as, for example, wet etching.

Next, the source drain contacts 136 are filled with a conductive material to form the source drain contacts 136 according to known techniques. The source drain contacts 136 may include any suitable conductive material, such as, for example, copper, ruthenium, aluminum, tungsten, cobalt, or alloys thereof. In some embodiments, a metal silicide is formed at the bottom of the contact trenches prior to filling them with the conductive material. According to the disclosed embodiments, the source drain contacts 136 are self-aligned to both the spacer material 118 and the source drain regions 122, and thus may be referred to as self-aligned contact structures; however, such is neither necessary nor required.

The source drain contacts 136 are conductive features which extend through the device region, or front-end-of-line, through the STI regions 112, and provide a conductive path between the frontside and the backside of the structure 100 as referenced herein. The function and/or purpose of such a conductive path will become apparent in subsequent description.

Next, the middle-of-line 138, including source drain contact vias 144 and gate contact vias 146 is formed according to known techniques. As disclosed herein, the source drain contact vias 144 and the gate contact vias 146 may generally be referred to as middle-of-line contacts. First, additional interlayer dielectric material is deposited according to known techniques. The additional dielectric layer 130 illustrated in the figures includes the additional interlayer dielectric material. Next, portions of the additional dielectric layer 130 are removed to expose the source drain contacts 136. The openings are then filled with a conductive material to form the middle-of-line contacts according to known techniques. The middle-of-line contacts include any suitable conductive material, such as, for example, copper, ruthenium, aluminum, tungsten, cobalt, or alloys thereof. In some embodiments, a metal silicide is formed at the bottom of the contact trenches prior to filling them with the conductive material.

The back-end-of-line 140 may include vias and metal lines which may be generally referred to as back-end-of-line interconnects. The vias and the metal lines are formed according to known techniques.

Finally, the carrier wafer 142 is secured to a top of the structure 100 according to an embodiment of the invention. The carrier wafer 142 is attached, or removably secured, to the back-end-of-line 140. In general, and not depicted, the carrier wafer 142 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 142 according to known techniques.

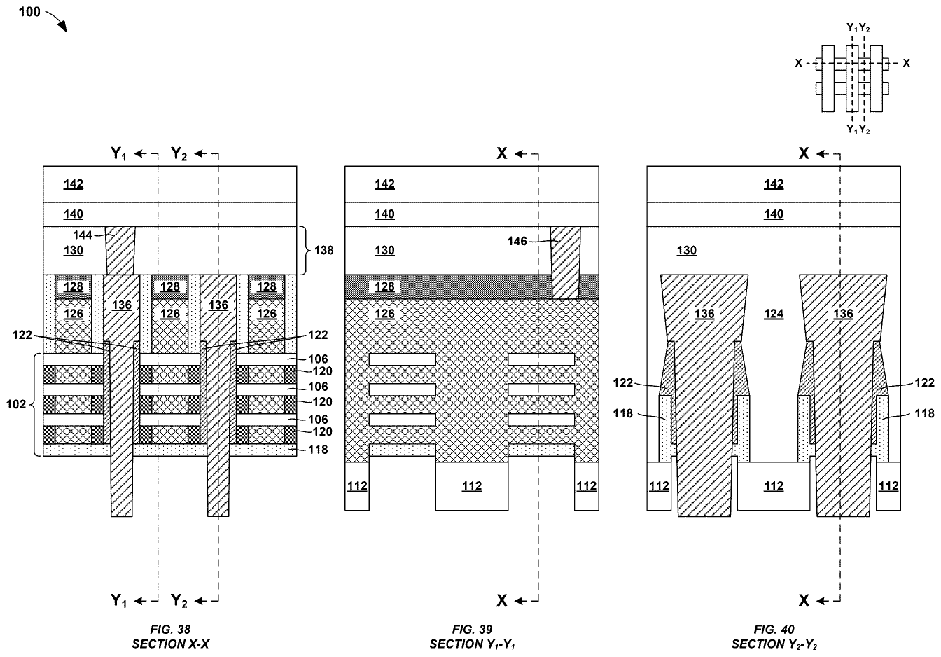

Referring now to FIGS. 38, 39, and 40, the structure 100 is shown after flipping the assembly and removing the substrate 110 according to an embodiment of the invention. FIG. 38 depicts a cross-sectional view of the structure 100 taken along line X-X, FIG. 39 depicts a cross-sectional view of the structure 100 taken along line Y₁-Y₁, and FIG. 40 depicts a cross-sectional view of the structure 100 taken along line Y₂-Y₂.

First, the structure 100 is flipped 180 degrees to prepare for backside processing. In general, backside processing includes fabrication or processing of the structure 100 opposite the active device and wiring layers. Next, the substrate 110 is recessed and removed according to known techniques. Specifically, the substrate 110 is recessed and removed selective to the STI regions 112 and the spacer material 118 as illustrated.

It is noted, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods as oriented in the drawing figures.

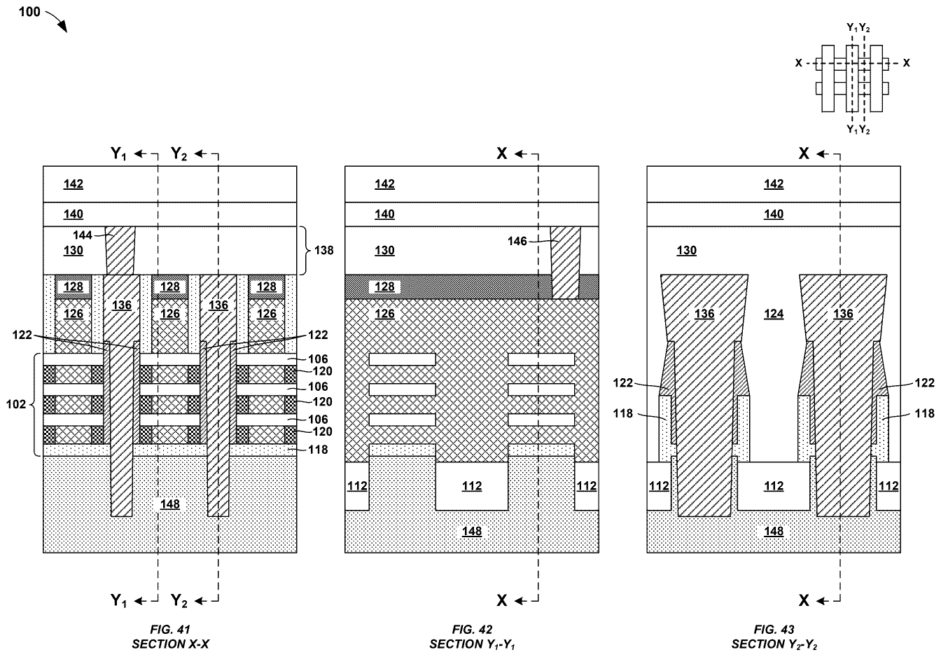

Referring now to FIGS. 41, 42, and 43, the structure 100 is shown after forming a backside dielectric layer 148 according to an embodiment of the invention. FIG. 41 depicts a cross-sectional view of the structure 100 taken along line X-X, FIG. 42 depicts a cross-sectional view of the structure 100 taken along line Y₁-Y₁, and FIG. 43 depicts a cross-sectional view of the structure 100 taken along line Y₂-Y₂.

The backside dielectric layer 148 is formed by blanket depositing an interlayer dielectric material over the structure 100 according to known techniques. Specifically, the backside dielectric layer 148 is formed on the spacer material 118 and covering exposed portions of the source drain contacts 136, as illustrated.

The backside dielectric layer 148 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the backside dielectric layer 148. Using a self-planarizing dielectric material as the backside dielectric layer 148 can avoid the need to perform a subsequent planarizing step.

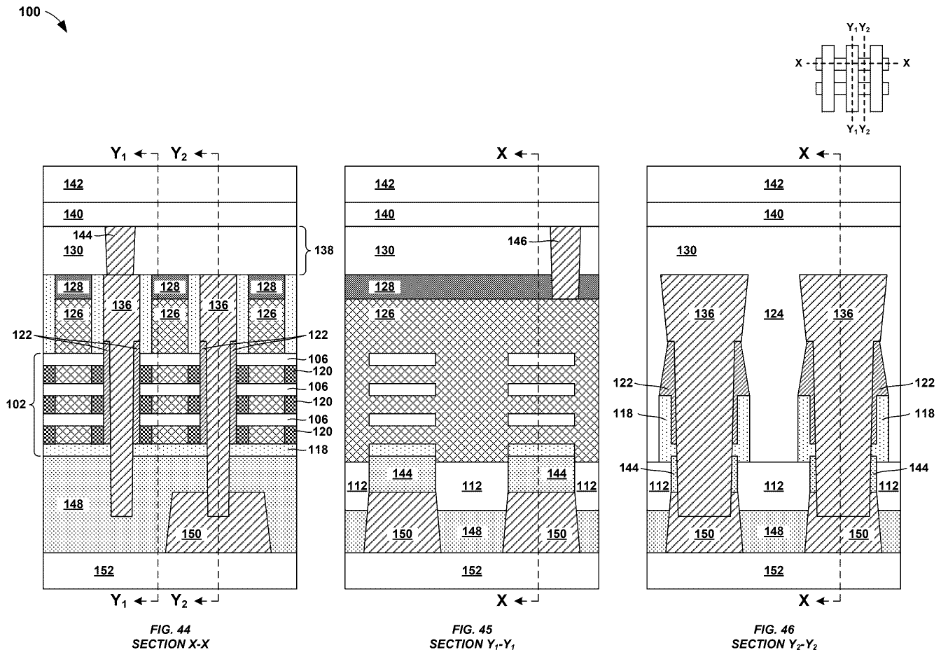

Referring now to FIGS. 44, 45, and 46, the structure 100 is shown after forming backside vias 150 and backside wiring layers 152 according to an embodiment of the invention. FIG. 44 depicts a cross-sectional view of the structure 100 taken along line X-X, FIG. 45 depicts a cross-sectional view of the structure 100 taken along line Y₁-Y₁, and FIG. 46 depicts a cross-sectional view of the structure 100 taken along line Y₂-Y₂.

First, a mask (not shown) is deposited and subsequently patterned to expose certain portions of the structure 100 according to known techniques. According to at least one embodiment, the mask can be an organic planarization layer (OPL) or a layer of material that is capable of being planarized or etched by known techniques. After depositing the mask, a dry etching technique is applied to pattern or recess the mask according to known techniques. The mask is patterned consistent with a size and a location of subsequently formed backside via structures. For example, after patterning the mask, portions of the source drain contacts 136 are exposed.

Exposed portions of the backside dielectric layer 148 are then selectively removed to form backside via trenches according to known techniques. Specifically, exposed portions of the backside dielectric layer 148 are removed using known etching techniques suitable to remove silicon-based dielectric materials selective to the mask. In an embodiment, the exposed portions of the backside dielectric layer 148 are removed using an anisotropic etch such as, for example, reactive ion etching (RIE).

Next, the backside via trenches are filled with a conductive material to form the backside vias 150 according to known techniques. The backside vias 150 may include any suitable conductive material, such as, for example, copper, ruthenium, aluminum, tungsten, cobalt, or alloys thereof.

After deposition, excess conductive material can be polished using known techniques until bottommost surfaces of the backside vias 150 are flush, or substantially flush, with bottommost surfaces of the backside dielectric layer 148, as illustrated. After polishing, bottommost surfaces of the backside vias 150 are substantially flat.

Finally, after forming the backside vias 150, the backside wiring layers 152 are subsequently formed according to known techniques. The backside wiring layers 152 typically include at least backside power rails and a backside power delivery network.

According to the embodiment illustrated in FIGS. 44-46, the transistor structures represented by the structure 100 have some distinctive notable features. For instance, the source drain contacts 136 extend through the source drain regions 122 from a frontside of the structure 100 to a backside of the structure 100. Further, portions of the source drain regions 122 remain in direct contact with sidewalls of each of the nanosheet channels 106. Doing so prevents undesirable resistance introduced by otherwise completely replacing the source drain regions 122 with the source drain contacts 136. As such, a lateral width of a bottom portion of the source drain contact 136 is less than a lateral width of a top portion of the source drain contact 136, as best illustrated in FIG. 44.

With continued reference to FIGS. 44-46, a bottommost surface of the source drain contact 136 is below a bottommost surface of the gate structures 126. Additionally, the structure 100 further includes a backside via 150 in direct contact with a bottom surface and sidewalls of the source drain contact 136. Additionally, topmost surfaces of the source drain contacts 136 are above topmost channels of the stack 102 of the nanosheet channels 106, and bottommost surfaces of the source drain contacts 136 are below bottommost channels of the stack 102 of the nanosheet channels 106. Moreover, the lateral width of a top portion of the source drain contact 136 measured in the x-direction is substantially equal to a lateral width of the source drain region 122 measured in the x-direction. Said differently, the lateral width of top portion of the source drain contact 136 is substantially equal to a distance between adjacent nanosheet stacks 102, as best illustrated in FIG. 44.

With continued reference to FIGS. 44-46, and according to an embodiment, the structure 100 includes a source drain region adjacent to a nanosheet stack, and a source drain contact extending through the source drain region from a frontside of the semiconductor structure to a backside of the semiconductor structure.

With continued reference to FIGS. 44-46, and according to an embodiment, the structure further includes a spacer material between and separating the nanosheet stack from an underlying backside dielectric layer, wherein the source drain contact extends through the spacer material.

With continued reference to FIGS. 44-46, and according to an embodiment, the structure further includes a gate surrounding individual nanosheet channels of the nanosheet stack, wherein a bottommost surface of the source drain contact is below a bottommost surface of the gate.

With continued reference to FIGS. 44-46, and according to an embodiment, the structure further includes a backside via in direct contact with a bottom portion of the source drain contact.

With continued reference to FIGS. 44-46, and according to an embodiment, the backside via directly contacts sidewalls and a bottommost surface of the source drain contact.

With continued reference to FIGS. 44-46, and according to an embodiment, the source drain contact comprises a first lateral width less than a second lateral width.

With continued reference to FIGS. 44-46, and according to an embodiment, source drain region comprises a lateral width substantially equal to the second lateral width of the source drain contact.

With continued reference to FIGS. 44-46, and according to an embodiment, the structure 100 includes a nanosheet stack comprising nanosheet channels, a source drain region adjacent to the nanosheet stack, where the source drain region directly contacts sidewalls of each of the nanosheet channels, and a source drain contact extending through the source drain region from a frontside of the semiconductor structure to a backside of the semiconductor structure, where a topmost surface of the source drain contact is above a topmost channel of the nanosheet channels, and where a bottommost surface of the source drain contact is below a bottommost channel of the nanosheet channels.

With continued reference to FIGS. 44-46, and according to an embodiment, the structure 100 includes a first source drain region adjacent to a nanosheet stack, a first source drain contact extending through the first source drain region from a frontside of the semiconductor structure to a backside of the semiconductor structure, a second source drain region adjacent to the nanosheet stack, and a second source drain contact extending through the second source drain region from a frontside of the semiconductor structure to a backside of the semiconductor structure.

Various examples may possibly be described by one or more of the following features in the following numbered clauses:

Clause 1: A semiconductor structure comprising: a source drain region adjacent to a nanosheet stack; and a source drain contact extending through the source drain region from a frontside of the semiconductor structure to a backside of the semiconductor structure.

Clause 2: The semiconductor structure according to clause 1, further comprising: a spacer material between and separating the nanosheet stack from an underlying backside dielectric layer, wherein the source drain contact extends through the spacer material.

Clause 3: The semiconductor structure according to clause 1 and 2, further comprising: a gate surrounding individual nanosheet channels of the nanosheet stack, wherein a bottommost surface of the source drain contact is below a bottommost surface of the gate.

Clause 4: The semiconductor structure according to clause 1, 2, and 3, further comprising: a backside via in direct contact with a bottom portion of the source drain contact.

Clause 5: The semiconductor structure according to clause 1, 2, 3, and 4, wherein the backside via directly contacts sidewalls and a bottommost surface of the source drain contact.

Clause 6: The semiconductor structure according to clause 1, 2, 3, 4, and 5, wherein the source drain contact comprises a first lateral width less than a second lateral width.

Clause 7: The semiconductor structure according to clause 1, 2, 3, 4, 5, and 6, wherein the source drain region comprises a lateral width substantially equal to the second lateral width of the source drain contact.

Clause 8: A semiconductor structure comprising: a nanosheet stack comprising nanosheet channels; a source drain region adjacent to the nanosheet stack, wherein the source drain region directly contacts sidewalls of each of the nanosheet channels; and a source drain contact extending through the source drain region from a frontside of the semiconductor structure to a backside of the semiconductor structure, wherein a topmost surface of the source drain contact is above a topmost channel of the nanosheet channels, and wherein a bottommost surface of the source drain contact is below a bottommost channel of the nanosheet channels.

Clause 9: The semiconductor structure according to clause 8, further comprising: a spacer material between and separating the nanosheet stack from an underlying backside dielectric layer, wherein the source drain contact extends through the spacer material.

Clause 10: The semiconductor structure according to clause 8 and 9, further comprising: a gate surrounding individual nanosheet channels of the nanosheet stack, wherein a bottommost surface of the source drain contact is below a bottommost surface of the gate.

Clause 11: The semiconductor structure according to clause 8, 9, and 10, further comprising: a backside via in direct contact with a bottom portion of the source drain contact.

Clause 12: The semiconductor structure according to clause 8, 9, 10, and 11, wherein the backside via directly contacts sidewalls and a bottommost surface of the source drain contact.

Clause 13: The semiconductor structure according to clause 8, 9, 10, 11, and 12, wherein the source drain contact comprises a first lateral width less than a second lateral width.

Clause 14: The semiconductor structure according to clause 8, 9, 10, 11, 12, and 13, wherein the source drain region comprises a lateral width substantially equal to the second lateral width of the source drain contact.

Clause 15: A semiconductor structure comprising: a first source drain region adjacent to a nanosheet stack; a first source drain contact extending through the first source drain region from a frontside of the semiconductor structure to a backside of the semiconductor structure; a second source drain region adjacent to the nanosheet stack; and a second source drain contact extending through the second source drain region from a frontside of the semiconductor structure to a backside of the semiconductor structure.

Clause 16: The semiconductor structure according to clause 15, further comprising: a gate surrounding individual nanosheet channels of the nanosheet stack, wherein a bottommost surface of the first source drain contact is below a bottommost surface of the gate, and wherein a bottommost surface of the second source drain contact is below the bottommost surface of the gate.

Clause 17: The semiconductor structure according to clause 15 and 16, further comprising: a backside via in direct contact with a bottom portion of each of the first source drain contact and the second source drain contact.

Clause 18: The semiconductor structure according to clause 15, 16, and 17, wherein the backside via directly contacts sidewalls and a bottommost surface of each of the first source drain contact and the second source drain contact.

Clause 19: The semiconductor structure according to clause 15, 16, 17, and 18, wherein each of the first source drain contact and the second source drain contact comprises a first lateral width less than a second lateral width.

Clause 20: The semiconductor structure according to clause 15, 16, 17, and 19, wherein each of the first source drain region and the second source drain region comprises a lateral width substantially equal to the second lateral width of each of the first source drain contact and the second source drain contact.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a source drain region adjacent to a nanosheet stack; and
a source drain contact extending through the source drain region from a frontside of the semiconductor structure to a backside of the semiconductor structure.

2. The semiconductor structure according to claim 1, further comprising:
a spacer material between and separating the nanosheet stack from an underlying backside dielectric layer, wherein the source drain contact extends through the spacer material.

3. The semiconductor structure according to claim 1, further comprising:
a gate surrounding individual nanosheet channels of the nanosheet stack, wherein a bottommost surface of the source drain contact is below a bottommost surface of the gate.

4. The semiconductor structure according to claim 1, further comprising:
a backside via in direct contact with a bottom portion of the source drain contact.

5. The semiconductor structure according to claim 4, wherein the backside via directly contacts sidewalls and a bottommost surface of the source drain contact.

6. The semiconductor structure according to claim 1, wherein the source drain contact comprises a first lateral width less than a second lateral width.

7. The semiconductor structure according to claim 6, wherein the source drain region comprises a lateral width substantially equal to the second lateral width of the source drain contact.

8. A semiconductor structure comprising:
a nanosheet stack comprising nanosheet channels;
a source drain region adjacent to the nanosheet stack, wherein the source drain region directly contacts sidewalls of each of the nanosheet channels; and
a source drain contact extending through the source drain region from a frontside of the semiconductor structure to a backside of the semiconductor structure, wherein a topmost surface of the source drain contact is above a topmost channel of the nanosheet channels, and wherein a bottommost surface of the source drain contact is below a bottommost channel of the nanosheet channels.

9. The semiconductor structure according to claim 8, further comprising:
a spacer material between and separating the nanosheet stack from an underlying backside dielectric layer, wherein the source drain contact extends through the spacer material.

10. The semiconductor structure according to claim 8, further comprising:
a gate surrounding individual nanosheet channels of the nanosheet stack, wherein a bottommost surface of the source drain contact is below a bottommost surface of the gate.

11. The semiconductor structure according to claim 8, further comprising:
a backside via in direct contact with a bottom portion of the source drain contact.

12. The semiconductor structure according to claim 11, wherein the backside via directly contacts sidewalls and a bottommost surface of the source drain contact.

13. The semiconductor structure according to claim 8, wherein the source drain contact comprises a first lateral width less than a second lateral width.

14. The semiconductor structure according to claim 13, wherein the source drain region comprises a lateral width substantially equal to the second lateral width of the source drain contact.

15. A semiconductor structure comprising:
a first source drain region adjacent to a nanosheet stack;
a first source drain contact extending through the first source drain region from a frontside of the semiconductor structure to a backside of the semiconductor structure;
a second source drain region adjacent to the nanosheet stack; and
a second source drain contact extending through the second source drain region from a frontside of the semiconductor structure to a backside of the semiconductor structure.

16. The semiconductor structure according to claim 15, further comprising:
a gate surrounding individual nanosheet channels of the nanosheet stack, wherein a bottommost surface of the first source drain contact is below a bottommost surface of the gate, and wherein a bottommost surface of the second source drain contact is below the bottommost surface of the gate.

17. The semiconductor structure according to claim 15, further comprising:
a backside via in direct contact with a bottom portion of each of the first source drain contact and the second source drain contact.

18. The semiconductor structure according to claim 17, wherein the backside via directly contacts sidewalls and a bottommost surface of each of the first source drain contact and the second source drain contact.

19. The semiconductor structure according to claim 15, wherein each of the first source drain contact and the second source drain contact comprises a first lateral width less than a second lateral width.

20. The semiconductor structure according to claim 19, wherein each of the first source drain region and the second source drain region comprises a lateral width substantially equal to the second lateral width of each of the first source drain contact and the second source drain contact.
